(19) United States
(12) Patent Application Publication
(10) Pub. No.: US 2008/0013363 A1
(43) Pub. Date: Jan. 17, 2008

(54) Operation method of nonvolatile memory device induced by pulse voltage

(75) Inventors: Dong-chul Kim, Suwon-si (KR); In-gyu Baek, Seoul (KR); Dong-seok Suh, Seoul (KR); Myoung-Jae Lee, Suwon-si (KR); Seung-eon Ahn, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/802,658

(22) Filed: May 24, 2007

(30) Foreign Application Priority Data
Jun. 27, 2006 (KR) 10-2006-0058096

(51) Int. Cl. G11C 11/21

(52) U.S. Cl. 365/148

(57) ABSTRACT

A threshold switching operation method of a nonvolatile memory device may be provided. In the threshold switching operation method of a nonvolatile memory a pulse voltage may be supplied to a metal oxide layer of the nonvolatile memory device. Accordingly, it may be possible to operate the nonvolatile memory device at a lower voltage with lower threshold switching current.

### PRIORITY STATEMENT

This application claims the benefit of priority to Korean Patent Application No. 10-2006-0058096, filed on Jun. 27, 2006, in the Korean Intellectual Property Office, the entire contents of which is incorporated herein in its entirety by reference.

### BACKGROUND

1. Field

Example embodiments relate to a method of operating a nonvolatile memory device, and for example, to a method of operating a nonvolatile memory device, in which a metal oxide layer may be formed between a lower electrode and an upper electrode, by supplying pulse voltage to the nonvolatile memory device so that the nonvolatile memory device may manifest switching characteristics, for example, the nonvolatile memory device may operate at a lower voltage with lower threshold current.

2. Description of Related Art

In a conventional Dynamic Random Access Memory (DRAM) process, a transistor/capacitor may form a unit cell. The smaller a device may be, the more difficult a capacitor process may be, making it difficult to fabricate a DRAM cell having higher throughput. Accordingly, there may be a need for a memory having non-volatile characteristics that may replace the conventional DRAMs. Accordingly, many attempts have been made to develop a next-generation memory that may satisfy demands for higher density and/or lower power consumption of DRAM, the non-volatile characteristics of flash memory, and/or higher-speed operation of SRAM.

Among nonvolatile memory devices, a Resistance Random Access Memory (RRAM) generally may include a transition metal oxide as a resistor of a storage node. For example, the RRAM may use the variable resistance characteristics of the transition metal oxide whose resistance value varies depending on voltage.

FIG. 1 is a cross-sectional view of a conventional nonvolatile memory device. Referring to FIG. 1, the nonvolatile memory device may include a substrate 100, a transistor 114 formed on the substrate 100, and/or a storage node 18 connected to and/or disposed on the transistor 114.

The transistor 114 may include a source 108S, a drain 108D, a channel 108C, a gate dielectric layer 104, and/or a gate electrode 106. The storage node 18 may include an upper electrode 16, a lower electrode 12, and/or a resistance layer 14 that may be interposed between the upper electrode 16 and the lower electrode 12 and/or formed of a transition metal oxide. A dielectric layer 110 may be interposed between the storage node 18 and the transistor 114. The storage node 18 may be connected to the transistor 114 via a conductive contact plug 118, and/or a plate electrode 112 may be disposed on the upper electrode 16.

The transition metal oxide may show threshold switching characteristics whereby switching may occur due to a variation in resistance, at and above a threshold voltage. Conventionally, a voltage equal to or higher than the threshold voltage is supplied to a metal oxide according to a DC voltage sweep, and a forming voltage may be supplied thereto in order to reduce the resistance of a resistor. However, in this case, the forming voltage may be higher, increasing the threshold voltage used for driving a device.

### SUMMARY

Example embodiments may provide a threshold switching operation method of a nonvolatile memory device, which may be capable of operating the nonvolatile memory device at a lower voltage with lower current.

According to an example embodiment, a threshold switching operation method of a nonvolatile memory device may include supplying a pulse voltage to a metal oxide layer of the nonvolatile memory device.

According to an example embodiment, the nonvolatile memory device may include a substrate, a lower electrode on the substrate, the metal oxide layer on the lower electrode, and/or an upper electrode on the metal oxide layer.

According to an example embodiment, a threshold switching operation method of a nonvolatile memory device may further include adjusting threshold switching characteristics of the nonvolatile memory device based on the supplied pulse voltage.

According to an example embodiment, adjusting threshold switching characteristics may lower a voltage required for threshold switching to occur in the nonvolatile memory device.

According to an example embodiment, adjusting threshold switching characteristics may lower a threshold current of the nonvolatile memory device.

According to an example embodiment, the metal oxide layer may be formed to a thickness of about 10 nm to 100 nm.

According to an example embodiment, the pulse voltage may be in a range from approximately 0.1 V to 50 V.

According to an example embodiment, a pulse duration of the pulse voltage may be in a range from approximately 10 ns to 20 μs.

According to an example embodiment, the metal oxide layer may be formed of at least one material selected from a group including of NiO, Nb₂O₅, TiO₂, Al₂O₃, V₂O₅, WO₃, ZnO, ZrO, and CoO.

According to an example embodiment, the metal oxide layer may be preferably formed of at least one material selected from a group consisting of NiO, Nb₂O₅, TiO₂, Al₂O₃, V₂O₅, WO₃, ZnO, ZrO, and CoO.

According to an example embodiment, the metal oxide layer may be formed of NiO by reacting Ni with oxygen under an oxygen partial pressure of about 5% to 15%.

According to an example embodiment, an electric field of the pulse voltage may be in a range from approximately 0.1 MV/cm to 5 MV/cm.

According to an example embodiment, an electric field of the pulse voltage may be inversely proportional to a pulse duration of the pulse voltage.

According to an example embodiment, the nonvolatile memory device may be in a set state when the pulse voltage is applied to the metal oxide layer. The pulse voltage may be 2 V supplied for a pulse duration of 5 μs.

According to an example embodiment, the nonvolatile memory device may be in a reset state when the pulse voltage is applied to the metal oxide layer. The pulse voltage may be 0.8 V supplied for a pulse duration of 10 μs or less.

According to an example embodiment, threshold switching may occur in the nonvolatile memory device when the pulse voltage is 4 V supplied for a pulse duration of 5 μs.

According to an example embodiment, the pulse voltage may be supplied such that a threshold current of the nonvolatile memory device may be 1 mA or less.

### BRIEF DESCRIPTION OF THE DRAWINGS

The above and/or other aspects and advantages will become more apparent more readily appreciated from the following detailed description of example embodiments taken in conjunction with the accompanying drawings of which:

FIG. 1 is a cross-sectional view of a conventional nonvolatile memory device;

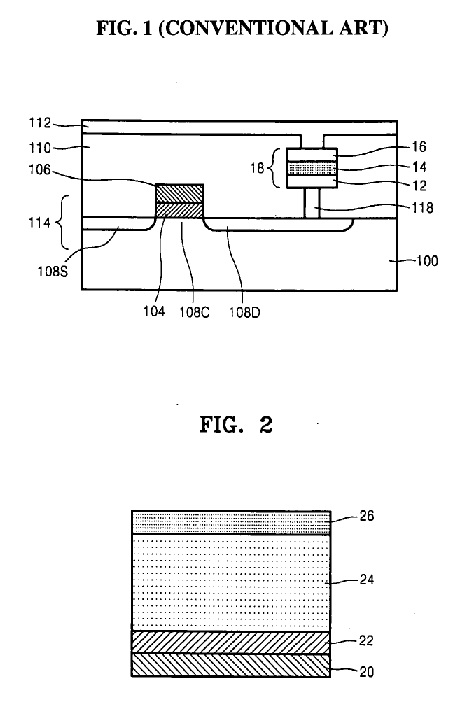

FIG. 2 is a schematic cross-sectional view of a nonvolatile memory device according to an example embodiment;

FIGS. 3A through 3C are example graphs illustrating threshold switching characteristics when a pulse voltage is supplied to a memory device according to an example embodiments; and

FIG. 4 is an example graph illustrating threshold switching characteristics of a conventional memory device according to a DC voltage sweep.

### DETAILED DESCRIPTION OF EXAMPLE EMBODIMENTS

Example embodiments will now be described more fully hereinafter with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

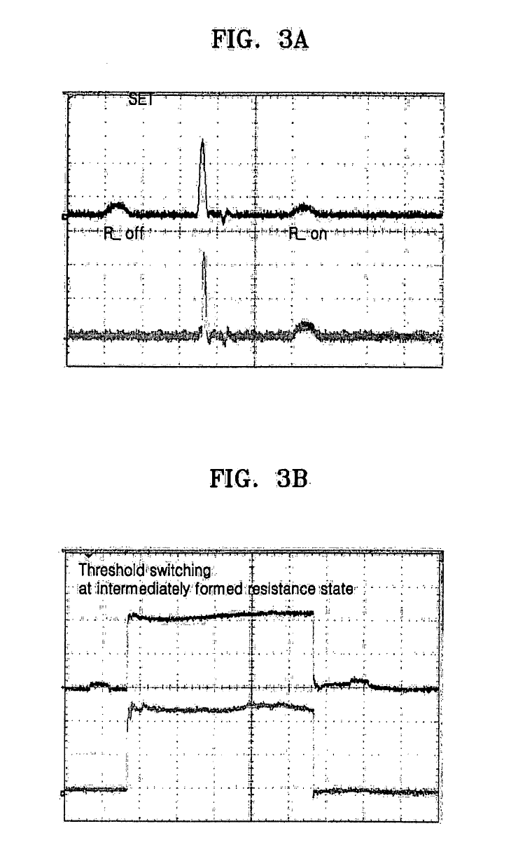

FIG. 2 is a schematic cross-sectional view of a memory device having a metal oxide layer according to an example embodiment. Referring to FIG. 2, the memory device may include a substrate 20, a lower electrode 22 on the substrate 20, a metal oxide layer 24 on the lower electrode 22, and/or an upper electrode 26 on the metal oxide layer 24.

The lower electrode 22 and/or the upper electrode 26 may be formed of a conductive material available as an electrode of a general semiconductor memory device. For example, the lower electrode 22 and/or the upper electrode 26 may be formed of at least one material selected from a group including Pt, Ru, Ir, Pd, Au, Cr, Ni, Cu, and TiN.

The lower electrode 22 and/or the upper electrode 26 may be formed according to electrode deposition for a general memory device. For example, they may be formed according to sputtering, electron beam deposition, or chemical vapor deposition. For example, the thickness of an electrode may be in a range from 10 nm to 200 nm.

The metal oxide layer 24 may be formed of a transition metal oxide having variable resistance characteristics. For example, the metal oxide layer 24 may be formed of at least one material selected from a group including NiO, Nb₂O₅, TiO₂, Al₂O₃, V₂O₅, WO₃, ZnO, ZrO, and CoO. If the metal oxide layer 24 is formed of NiO, it may be possible to obtain the metal oxide layer 24 by reacting Ni with oxygen under an oxygen partial pressure of about 5% to 15%, which may induce variable resistance characteristics.

The metal oxide layer 24 containing metal and oxide may be fabricated by using sputtering, pulse laser deposition, chemical vapor deposition, organic metal vapor deposition, a sol-gel process, or spray pyrolysis.

According to an example embodiment, the metal oxide layer 24 (for example, a NiO layer) may be formed under an oxygen partial pressure of 5% to 15%. In an example embodiment, the metal oxide layer 24 may preferably be formed to a thickness of 10 nm to 100 nm.

Threshold switching according to an example embodiment will now be described. A pulse voltage ranging from about 0.1 V to 50 V may be supplied to a memory device illustrated in FIG. 2. The electric field of the pulse voltage may be in a range from 0.1 MV/cm to 5 MV/cm. For example, the duration of the pulse may be inversely proportional to the electric field of the pulse voltage, and/or controlled within a range from 10 ns to 20 μs. For example, the memory device illustrated in FIG. 2 may show threshold switching characteristics. When the duration of the pulse exceeds 20 μs, the memory device illustrated in FIG. 2 need not show threshold switching characteristics.

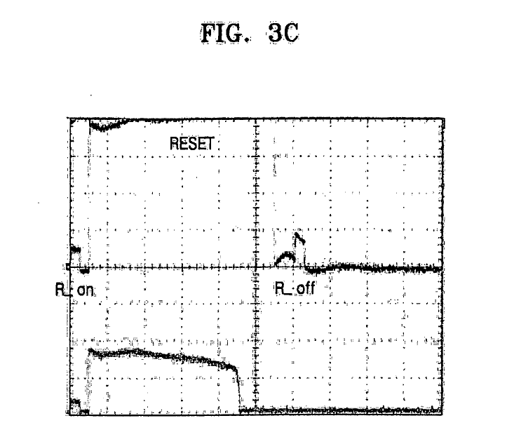

FIGS. 3A through 3C are example graphs illustrating threshold switching characteristics when pulse voltage is supplied to a memory device having a NiO layer as a metal oxide layer, according to example embodiments. FIG. 3A is an example graph illustrating a set state of the memory device when 2V is supplied to the memory device for 5 μs. FIG. 3B is an example graph illustrating threshold switching characteristics of the memory device when 4V is supplied to the memory device for 5 μs. FIG. 3C is an example graph illustrating a reset state of the memory device when 0.8V is supplied to the memory device for 10 μs or less.

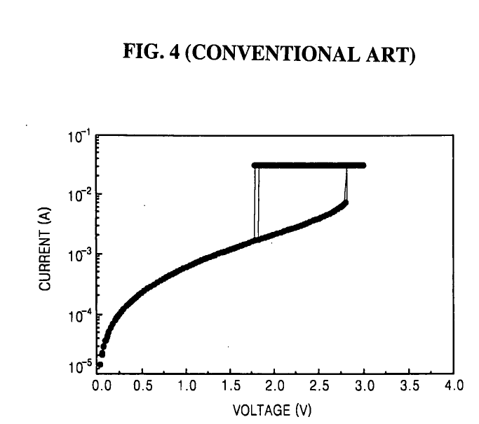

FIG. 4 is an example I-V graph illustrating threshold switching characteristics of a conventional memory device having an NiO layer as a metal oxide layer, according to DC voltage sweep. In order to make a conventional memory device having an NiO layer show threshold switching characteristics, NiO may be deposited under higher oxygen partial pressure of about 20% or more. For example, a voltage equal to or higher than a threshold voltage may be supplied to a metal oxide such as NiO and/or a forming voltage may be supplied thereto according to a DC voltage sweep. Referring to FIG. 4, the threshold current Tth may be approximately 10 mA.

Referring to FIGS. 3A through 3C and 4, when a pulse voltage is supplied to a memory device according to an example embodiment, threshold switching may occur even when a voltage lower than a forming voltage used in a conventional DC voltage sweep is supplied. The threshold current may be 0.1 mA or less when a pulse voltage is supplied in the case of a threshold switching operation method of a memory device according to an example embodiment, but the threshold current may be 10 mA DC when a voltage sweep is performed in the case of a conventional threshold switching operation method of a memory device.

According to example embodiments, it may be possible to operate a nonvolatile memory device in which a metal oxide layer may be formed between a lower electrode and an upper electrode, at a lower voltage with lower threshold current by supplying a pulse voltage to the nonvolatile memory device.

Although example embodiments have been shown and described in this specification and figures, it would be appreciated by those skilled in the art that changes may be made to the illustrated and/or described example embodiments without departing from their principles and spirit, the scope of which is defined by the claims and their equivalents.

What is claimed is:

1. A threshold switching operation method of a nonvolatile memory device, the method comprising:
supplying a pulse voltage to a metal oxide layer of the nonvolatile memory device.

2. The method of claim 1, wherein the nonvolatile memory device includes a substrate, a lower electrode on the substrate, the metal oxide layer on the lower electrode, and an upper electrode on the metal oxide layer.

3. The method of claim 1, further comprising:
adjusting threshold switching characteristics of the nonvolatile memory device based on the supplied pulse voltage.

4. The method of claim 3, wherein adjusting threshold switching characteristics lowers a voltage required for threshold switching to occur in the nonvolatile memory device.

5. The method of claim 3, wherein adjusting threshold switching characteristics lowers a threshold current of the nonvolatile memory device.

6. The method of claim 1, wherein the metal oxide layer is formed to a thickness of about 10 nm to 100 nm.

7. The method of claim 1, wherein the pulse voltage is in a range from approximately 0.1 V to 50 V.

8. The method of claim 1, wherein a pulse duration of the pulse voltage is in a range from approximately 10 ns to 20 us.

9. The method of claim 1, wherein the metal oxide layer is formed of at least one material selected from a group including NiO, Nb₂O₅, TiO₂, Al₂O₃, V₂O₅, WO₃, ZnO, ZrO, and CoO.

10. The method of claim 1, wherein the metal oxide layer is formed of at least one material selected from a group consisting of NiO, Nb₂O₅, TiO₂, Al₂O₃, V₂O₅, WO₃, ZnO, ZrO, and CoO.

11. The method of claim 1, wherein the metal oxide layer is formed of NiO by reacting Ni with oxygen under an oxygen partial pressure of about 5% to 15%.

12. The method of claim 1, wherein an electric field of the pulse voltage is in a range from approximately 0.1 MV/cm to 5 MV/cm.

13. The method of claim 1, wherein a pulse duration of the pulse voltage is inversely proportional to an electric field of the pulse voltage.

14. The method of claim 1, wherein the nonvolatile memory device is in a set state when the pulse voltage is applied to the metal oxide layer.

15. The method of claim 14, wherein the pulse voltage is 2 V supplied for a pulse duration of 5 μs.

16. The method of claim 1, wherein the nonvolatile memory device is in a reset state when the pulse voltage is supplied to the metal oxide layer.

17. The method of claim 16, wherein the pulse voltage is 0.8 V supplied for a pulse duration of 10 μs or less.

18. The method of claim 1, wherein threshold switching occurs in the nonvolatile memory device when the pulse voltage is 4 V supplied for a pulse duration of 5 μs.

19. The method of claim 1, wherein the pulse voltage is supplied such that a threshold current of the nonvolatile memory device is 1 mA or less.
